(19) United States
(12) Patent Application Publication
(10) Pub. No.: US 2025/0328087 A1
(43) Pub. Date: Oct. 23, 2025

(54) SYSTEM AND METHOD FOR DETERMINING OVERLAY MEASUREMENT OF A SCANNING TARGET USING MULTIPLE WAVELENGTHS

(71) Applicant: KLA Corporation, Milpitas, CA (US)

(72) Inventors: Itay Gdor, Tel-Aviv (IL); Yuval Lubashevsky, Haifa (IL); Nickolai Isakovitch, Tel-Aviv (IL); Yoav Grauer, Haifa (IL); Alon Alexander Volfman, Migdal Haemek (IL)

(21) Appl. No.: 18/642,417

(22) Filed: Apr. 22, 2024

(51) Int. Cl. G03F 7/00; G03F 9/00

(52) U.S. Cl. CPC G03F 7/70633; G03F 7/7085; G03F 9/7088

(57) ABSTRACT

A method may include illuminating an overlay target on a sample as the sample is translated along a stage-scan direction with two or more illumination beams. The two or more illumination beams include at least a first illumination beam having a first wavelength and a second illumination beam having a second wavelength, where the first wavelength is different than the second wavelength. The method may further include receiving time-varying interference signals from two or more photodetectors associated with a first-layer grating feature and a second-layer grating feature of a grating-over-grating structure. The first-layer grating feature may have a first pitch and the second-layer grating feature may have a second pitch different than the first pitch. The method may further include determining an overlay measurement between one of the first-layer grating feature and the second-layer grating feature of the sample based on the time-varying interference signals.

### TECHNICAL FIELD

The present disclosure relates generally to overlay metrology and, more particularly, to scanning scatterometry overlay metrology.

### BACKGROUND

Overlay metrology generally refers to measurements of the relative alignment of layers on a sample such as, but not limited to, semiconductor devices. An overlay measurement, or a measurement of overlay error, typically refers to a measurement of the misalignment of fabricated features on two or more sample layers. In a general sense, proper alignment of fabricated features on multiple sample layers is necessary for proper functioning of the device.

Demands to decrease feature size and increase feature density are resulting in correspondingly increased demand for accurate and efficient overlay metrology systems. Metrology systems typically generate metrology data associated with a sample by measuring or otherwise inspecting overlay metrology targets distributed across the sample.

Overlay metrology targets are typically designed to provide diagnostic information regarding the alignment of multiple layers of a sample by characterizing an overlay target having target features located on sample layers of interest. Further, the overlay alignment of the multiple layers is typically determined by aggregating overlay measurements of multiple overlay targets at various locations across the sample.

Often a single wavelength is used to measure multiple layers of the overlay target. However, in some cases, the sample morphology and/or material of the sample do not allow for a single wavelength to measure all of the layers within the overlay target. For example, the wavelength that matches the current layer (e.g., photo resist) may not penetrate through the sample and thus does not reach the previous layer.

Therefore, it is desirable to provide systems and methods for curing the above deficiencies.

### SUMMARY

An overlay metrology system is disclosed, in accordance with one or more embodiments of the present disclosure. In embodiment, the overlay metrology system includes an illumination sub-system. In embodiments, the illumination sub-system includes one or more illumination sources configured to generate two or more illumination beams, where the two or more illumination beams include at least a first illumination beam having a first wavelength and a second illumination beam having a second wavelength, where the first wavelength is different than the second wavelength. In embodiments, the illumination sub-system includes one or more illumination optics configured to direct the two or more illumination beams to an overlay target on a sample as the sample is scanned relative to the two or more illumination beams along a scan direction when implementing a metrology recipe, where the overlay target in accordance with the metrology recipe includes a grating-over-grating structure in one or more cells, where the grating-over-grating structure includes at least a first-layer grating feature on a first layer of the sample and a second-layer grating feature on a second layer of the sample, where the first-layer grating feature has a first pitch and the second-layer grating feature has a second pitch different than the first pitch. In embodiments, the overlay metrology system includes a collection sub-system. In embodiments, the collection sub-system includes two or more photodetectors located in a pupil plane to capture at least one diffraction order of the first illumination beam from the first-layer grating feature and at least one diffraction order of the second illumination beam from the second-layer grating feature of the grating-over-grating structure in the one or more cells when implementing the metrology recipe. In embodiments, the overlay metrology system includes a controller communicatively coupled to the two or more photodetectors. In embodiments, the controller includes one or more processors configured to execute program instructions causing the one or more processors to: receive time-varying interference signals from the two or more photodetectors associated with the first-layer grating feature and the second-layer grating feature of the grating-over-grating structure in the one or more cells as the overlay target is scanned in accordance with the metrology recipe and determine an overlay measurement between one of the first-layer grating feature and the second-layer grating feature of the sample based on the time-varying interference signals.

An overlay metrology system is disclosed, in accordance with one or more embodiments of the present disclosure. In embodiments, the overlay metrology system includes a controller communicatively coupled to two or more photodetectors. In embodiments, the controller includes one or more processors configured to execute program instructions causing the one or more processors to: receive time-varying interference signals from the two or more photodetectors associated with a first-layer grating feature and a second-layer grating feature of a grating-over-grating structure in one or more cells as an overlay target is scanned in accordance with a metrology recipe, where the two or more photodetectors are located in a pupil plane to capture at least one diffraction order of a first illumination beam from the first-layer grating feature and at least one diffraction order of a second illumination beam from the second-layer grating feature of the grating-over-grating structure in the one or more cells when implementing the metrology recipe, where the first illumination beam has a first wavelength and the second illumination beam has a second wavelength, where the first wavelength is different than the second wavelength, where the first-layer grating feature has a first pitch and the second-layer grating feature has a second pitch different than the first pitch; and determine an overlay measurement between one of the first-layer grating feature and the second-layer grating feature of the sample based on the time-varying interference signals.

A method is disclosed, in accordance with one or more embodiments of the present disclosure. In embodiments, the method includes illuminating an overlay target on a sample as the sample is translated along a scan direction with two or more illumination beams, where the two or more illumination beams include at least a first illumination beam having a first wavelength and a second illumination beam having a second wavelength, where the first wavelength is different than the second wavelength. In embodiments, the method includes receiving time-varying interference signals from two or more photodetectors associated with a first-layer grating feature and a second-layer grating feature of a grating-over-grating structure in one or more cells as the overlay target is scanned in accordance with a metrology recipe, where the two or more photodetectors are located in a pupil plane to capture at least one diffraction order of the first illumination beam from the first-layer grating feature and at least one diffraction order of the second illumination beam from the second-layer grating feature of the grating-over-grating structure in the one or more cells when implementing the metrology recipe, where the first-layer grating feature has a first pitch and the second-layer grating feature has a second pitch different than the first pitch. In embodiments, the method includes determining an overlay measurement between one of the first-layer grating feature and the second-layer grating feature of the sample based on the time-varying interference signals.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures in which:

FIG. 1A is a block diagram view of a system for performing scatterometry overlay metrology on overlay targets, in accordance with one or more embodiments of the present disclosure.

FIG. 1B is a schematic view of an overlay metrology sub-system, in accordance with one or more embodiments of the present disclosure.

FIG. 2 is a conceptual view of a cell of an overlay target on a sample, in accordance with one or more embodiments of the present disclosure.

FIG. 3A is a top view of an illumination pupil in an illumination pupil plane of the overlay metrology sub-system, in accordance with one or more embodiments of the present disclosure.

FIG. 3B is a top view of a collection pupil in the collection pupil plane of the overlay metrology sub-system, in accordance with one or more embodiments of the present disclosure.

FIG. 3C is a top view of a collection pupil in the collection pupil plane of the overlay metrology sub-system, in accordance with one or more embodiments of the present disclosure.

FIG. 3D is a top view of a collection pupil in the collection pupil plane of the overlay metrology sub-system, in accordance with one or more embodiments of the present disclosure.

FIG. 3E is a top view of a collection pupil in the collection pupil plane of the overlay metrology sub-system, in accordance with one or more embodiments of the present disclosure.

FIG. 3F is a signal intensity plot for a single wavelength system.

FIG. 3G is a signal intensity plot for a multiple wavelength system, in accordance with one or more embodiments of the present disclosure.

FIG. 4 is a flow diagram illustrating steps performed in a method for scanning overlay metrology of overlay targets using multiple wavelengths, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to scanning scatterometry overlay of overlay targets using two or more illumination beams generated by one or more illumination sources, where the two or more illumination beams have different wavelengths. For example, the overlay target may include a grating-over-grating structure formed of a first-layer grating feature on a first layer of the sample and a second-layer grating feature on a second layer of the sample, where the first-layer grating feature and the second-layer grating feature have different pitches. In some instances, at least one diffraction order of the first illumination beam from the first-layer grating feature fully overlaps with at least diffraction order of the second illumination beam from the second-layer grating feature. Further, an intensity of the time-varying interference signals associated with the first-layer grating feature may be equal to an intensity of the time-varying interference signals associated with the second-layer grating feature. By way of another example, a respective wavelength of a respective illumination beam may be selected based on one or more properties of time-varying signals of a respective grating feature, such that a contrast above a selected threshold (i.e., maximum contrast) is achieved. In a non-limiting example, the first-layer grating feature may be formed of a first material that absorbs the second wavelength of the second illumination beam. Further, at least one of the second-layer grating feature or an intermediate-layer grating feature may be formed of a second material (different than the first material) that absorbs the first wavelength of the first illumination beam.

It is contemplated that the system and method for determining overlay measurement of a scanning target using multiple wavelengths may provide a number of advantages over single wavelength techniques. For example, material properties like absorption may limit the ability to generate high signal-to-noise (SNR) signals from top and bottom gratings using a single wavelength. However, the use of multiple wavelengths in the present disclosure allows measurements in these cases such that high SNR signals from both top and bottom gratings are generated. Further, the use of single-wavelength light typically results in different amounts of overlap between diffraction orders of interest with zero-order light, which may disparately impact the SNR of the associated time-varying signals from top and bottom gratings. However, the use of multiple wavelengths in the present disclosure allows for the same amount of overlap of diffraction orders of interest with zero-order light to provide equal SNR.

For the purposes of the present disclosure, the term “scatterometry metrology” is used to broadly encompass the terms “scatterometry-based metrology” and “diffraction-based metrology” in which a sample having periodic features on one or more sample layers is illuminated with an illumination beam having a limited angular extent and one or more distinct diffraction orders are collected for the measurement. Further, the term “scanning metrology” is used to describe metrology measurements generated when a sample is in motion relative to illumination used for a measurement. In a general sense, scanning metrology may be implemented by moving the sample, the illumination, or both.

Embodiments of the present disclosure are directed to systems and methods for scanning overlay metrology based on time-varying interference signals from grating-over-grating structures in a collection pupil plane. It is contemplated herein that measurement conditions leading to overlapping diffraction orders of a grating-over-grating structure may lead to interference. Such interference signals may include information associated with asymmetries in the target structure such as, but not limited to, overlay between the gratings, and the like. It is further contemplated herein that scanning the grating-over-grating structure relative to an illumination beam (or vice versa) may provide characterization of the position-dependent overlay of the grating-over-grating structure and may thus enable the determination of asymmetries such as, but not limited to, overlay.

Embodiments of the present disclosure are directed to scanning scatterometry overlay metrology based on time-varying interference signals associated with overlapping diffraction lobes from gratings of a grating-over-grating structure. For instance, scanning-based scatterometry measurement techniques may include fast detectors to capture time-varying interference signals generated as the sample is scanned. The detectors may be placed in the pupil plane at locations of overlap between selected diffraction orders to capture time-varying interference signals as the sample is scanned. Various non-limiting scanning scatterometry overlay metrology techniques are described in U.S. Pat. No. 11,300,405 issued on Apr. 12, 2022; U.S. Pat. No. 11,378,394, issued on Jul. 5, 2022; U.S. Patent Publication No. 2023/0314319, published on Oct. 5, 2023; U.S. Pat. No. 11,796,925, issued on Oct. 24, 2023; U.S. patent application Ser. No. 18/099,798, filed on Jan. 20, 2023; U.S. patent application Ser. No. 18/110,746, filed on Feb. 16, 2023; U.S. patent application Ser. No. 18/230,542, filed on Aug. 4, 2023; U.S. patent application Ser. No. 18/372,444, filed on Sep. 25, 2023; and U.S. patent application Ser. No. 18/372,531, filed on Sep. 25, 2023, which are all incorporated herein by reference in their entireties. It is contemplated herein that the systems and methods of the above incorporated references may be extended or otherwise adapted to provide overlay measurements of grating-over-grating structures.

In embodiments, an overlay metrology system includes photodetectors located in a pupil plane at positions corresponding to diffraction lobes from grating-over-grating structures. For example, photodetectors may be located at locations of overlap between first-order diffraction lobes and 0-order diffraction (e.g., specular reflection). It is contemplated herein that these combined diffraction orders will exhibit time-varying interference signals (e.g., AC signals) during a scanning measurement, which may be captured using the photodetectors. For example, the properties of the grating-over-grating structures (e.g., pitches of the constituent gratings) and/or the measurement conditions (e.g., illumination wavelength, illumination incidence angle, collection angle, or the like) may be selected to provide that positive and negative diffraction orders associated with combined diffraction by the gratings of the grating-over-grating structure are collected by the system and captured by the photodetectors.

Embodiments of the present disclosure are directed to providing recipes for configuring an overlay metrology sub-system. An overlay metrology sub-system is typically configurable according to a recipe including a set of parameters for controlling various aspects of an overlay measurement such as, but not limited to, the illumination of a sample, the collection of light from the sample, or the position of the sample during a measurement. In this way, the overlay metrology sub-system may be configured to provide a selected type of measurement for one or more overlay target designs of interest. For example, a metrology recipe may include illumination parameters such as, but not limited to, a number of illumination beams, an illumination wavelength, an illumination pupil distribution (e.g., a distribution of illumination angles and associated intensities of illumination at those angles), a polarization of incident illumination, or a spatial distribution of illumination. By way of another example, a metrology recipe may include collection parameters such as, but not limited to, a collection pupil distribution (e.g., a desired distribution of angular light from the sample to be used for a measurement and associated filtered intensities at those angles), collection field stop settings to select portions of the sample of interest, polarization of collected light, wavelength filters, positions of one or more detectors (e.g., photodetectors) or parameters for controlling the one or more detectors. By way of a further example, a metrology recipe may include various parameters associated with the sample position during a measurement such as, but not limited to, a sample height, a sample orientation, whether a sample is static during a measurement, or whether a sample is in motion during a measurement (along with associated parameters describing the speed, scan pattern, or the like).

In embodiments, the properties of the grating-over-grating structures (e.g., pitches of the constituent gratings, or the like) and the measurement conditions (e.g., illumination wavelength, illumination incidence angle, collection angle, or the like) are arranged or otherwise selected (e.g., using a metrology recipe) to provide a selected distribution of diffraction and/or combined diffraction orders and to further provide that photodetectors are placed at suitable locations to capture these orders to generate time-varying interference signals of interest.

It is further contemplated that the systems and methods disclosed herein may provide sensitive overlay metrology at a high throughput. For example, the non-imaging configuration enables the use of fast photodetectors suitable for fast scan speeds. As a non-limiting example, photodetectors having a bandwidth of 1 GHz may enable scan speeds of approximately 10 centimeters per second on targets having a pitch of 1 micrometer.

The grating-over-grating structures may generally be formed as portions of overlay targets and may generally be located anywhere on the sample. Further, overlay targets may include one or more measurement cells. An overlay measurement may then be based on any combination of measurements of the various cells of the overlay target. For example, multiple cells of an overlay target may be designed with different intended offsets (e.g., gratings in the various layers of the sample that are intentionally misaligned with known offset values), which may improve the accuracy and/or sensitivity of the measurement.

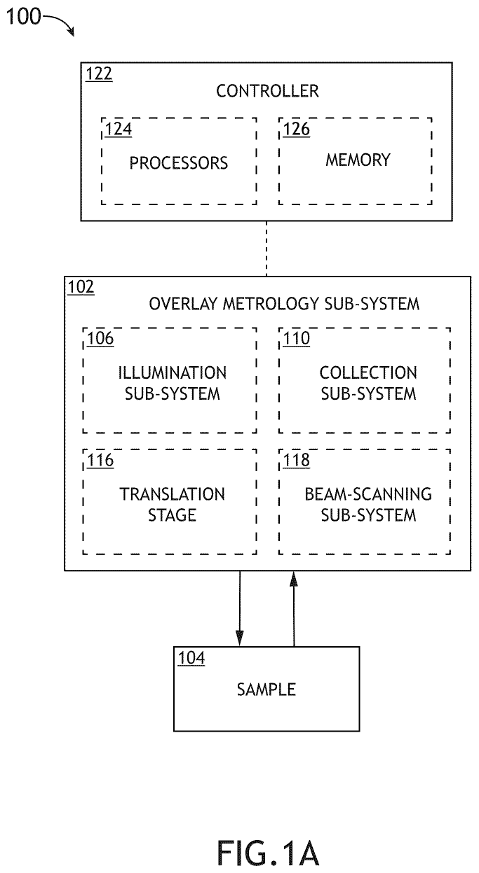

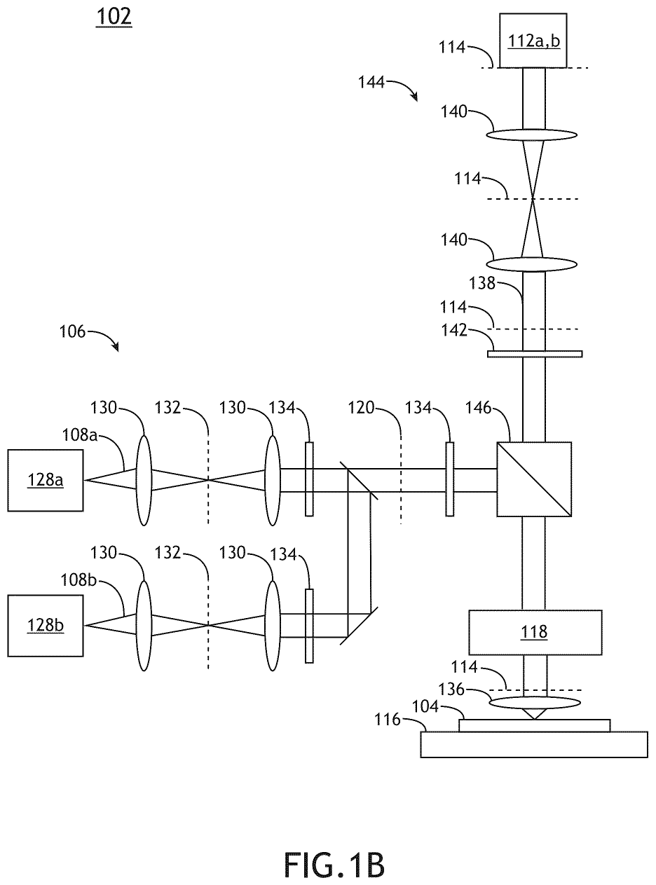

Referring now to FIGS. 1A-4, systems and methods for determining overlay measurements of a scanning target using multiple wavelengths, are described in greater detail in accordance with one or more embodiments of the present disclosure.

FIG. 1A illustrates a block diagram view of an overlay metrology system 100 for performing scatterometry overlay metrology on a grating-over-grating structure metrology target, in accordance with one or more embodiments of the present disclosure.

In embodiments, the overlay metrology system 100 includes an overlay metrology sub-system 102 to perform scatterometry overlay measurements of a sample 104. For example, the overlay metrology sub-system 102 may perform scatterometry overlay measurements on portions of the sample 104 having grating-over-grating structures.

FIG. 1B illustrates a schematic view of the overlay metrology sub-system 102, in accordance with one or more embodiments of the present disclosure.

In embodiments, the overlay metrology sub-system 102 includes an illumination sub-system 106 to generate illumination in the form of two or more illumination beams 108 having different wavelengths to illuminate the sample 104 and a collection sub-system 110 to collect light from the illuminated sample 104. For example, the two or more illumination beams 108 may be angularly limited on the sample 104 such that grating-over-grating structures (e.g., in one or more cells of an overlay target) may generate discrete diffraction orders. Further, the two or more illumination beams 108 may be spatially limited such that they may illuminate selected portions of the sample 104. For instance, each of the two or more illumination beams 108 may be spatially limited to illuminate a particular cell of an overlay target. In embodiments, the one or more illumination beams 108 underfill a particular cell of an overlay target.

In embodiments, the illumination sub-system 106 includes one or illumination sources 128 configured to generate two or more illumination beams 108 having different wavelengths. For example, the two or more illumination beams 108 may include at least a first illumination beam 108a having a first wavelength and a second illumination beam 108b having a second wavelength, where the first wavelength is different than the second wavelength. In a non-limiting example, the first illumination beam 108a may have a wavelength Δ₁ that is higher than a wavelength Δ₂ of the second illumination beam 108b. The two or more illumination beams 108a,b from the one or more illumination sources 128 may include one or more selected wavelengths of light including, but not limited to, ultraviolet (UV) radiation, visible radiation, or infrared (IR) radiation.

Although FIG. 1B depicts two illumination sources where each illumination source 128 generates a respective illumination beam, it is contemplated herein that the two or more illumination beams 108a,b may be generated using a variety of techniques. In embodiments, the illumination sub-system 106 includes a first illumination source 128a configured to generate the first illumination beam 108a and a second illumination source 128b configured to generate the second illumination beam 108b, where the first and second illumination beams 108a,b have different wavelengths. In embodiments, the illumination sub-system 106 includes one or more beamsplitters to split illumination from the one or more illumination sources 128 into the two or more illumination beams 108. In embodiments, the illumination sub-system 106 includes two or more apertures at an illumination field plane 132. In embodiments, at least one illumination source 128 generates two or more illumination beams 108 directly. In a general sense, each illumination beam 108 may be considered to be a part of a different illumination channel regardless of the technique in which the various illumination beams 108 are generated.

In embodiments, the collection sub-system 110 may collect at least some diffraction orders associated with diffraction of the illumination beam 108 from a grating-over-grating structure. In embodiments, the collection sub-system 110 may include at least two photodetectors 112 positioned in a collection pupil plane 114 at locations associated with time-varying interference signals indicative of overlay. For example, as will be described in greater detail below, suitable locations for the photodetectors 112 may include, but are not limited to, locations associated with positive and negative diffraction orders or locations associated with overlap between diffraction orders of the constituent gratings of a grating-over-grating structure (e.g., an overlap region between first-order diffraction of each grating and 0-order diffraction). In embodiments, the collection sub-system 110 may include an area sensor positioned in a collection pupil plane 114 at a location associated with time-varying interference signals indicative of overlay.

In embodiments, the intensity of at least one of the two or more illumination beams 108 may be adjusted such that the intensity of the respective time-varying interference signals are substantially equal (e.g., equal within a selected tolerance). It is contemplated herein that the intensity of the two or more illumination beams may be adjusted using any suitable technique. For example, the illumination sub-system 106 may include one or more neutral-density (ND) filters (e.g., fixed ND filters, variable ND filters of the like) configured to adjust an intensity of a respective illumination beam. By way of another example, the output power of a respective illumination source 128 may be used to adjust the intensity of a respective illumination beam.

In embodiments, the overlay metrology sub-system 102 includes a translation stage 116 to scan the sample 104 through a measurement field of view of the overlay metrology sub-system 102 during a measurement to implement scanning metrology.

In embodiments, the overlay metrology sub-system 102 includes a beam-scanning sub-system 118 configured to modify or otherwise control a position of at least one illumination beam 108 on the sample 104. For example, the beam-scanning sub-system 118 may scan an illumination beam 108 in a direction orthogonal to a scan direction (e.g., a direction in which the translation stage 116 scans the sample 104) during a measurement.

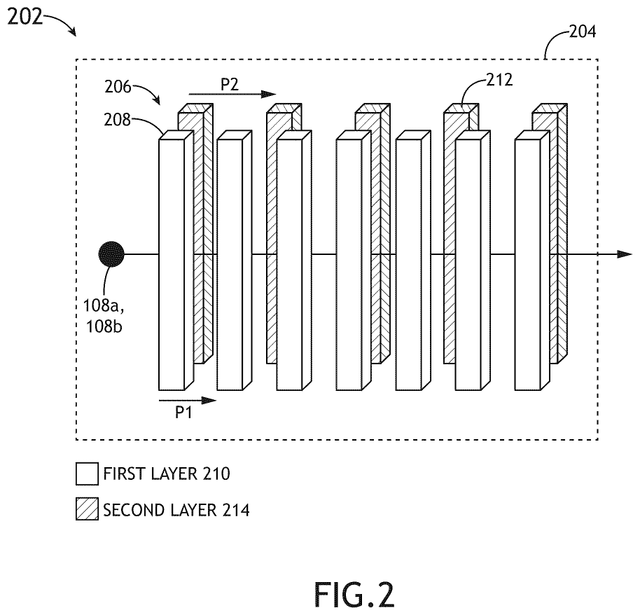

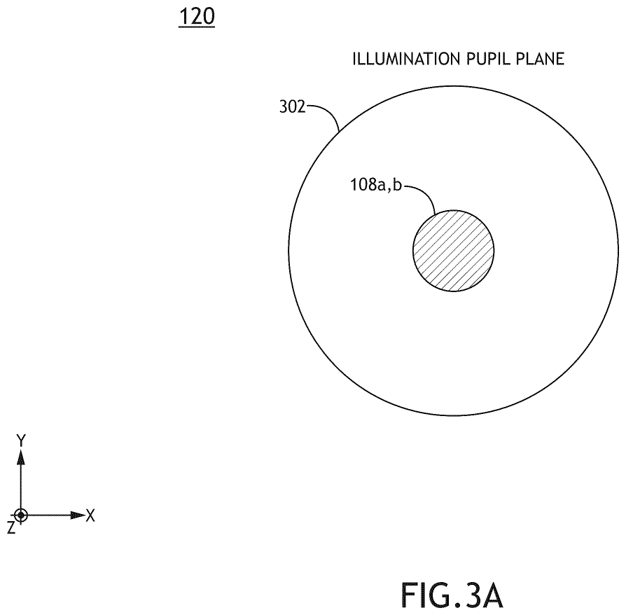

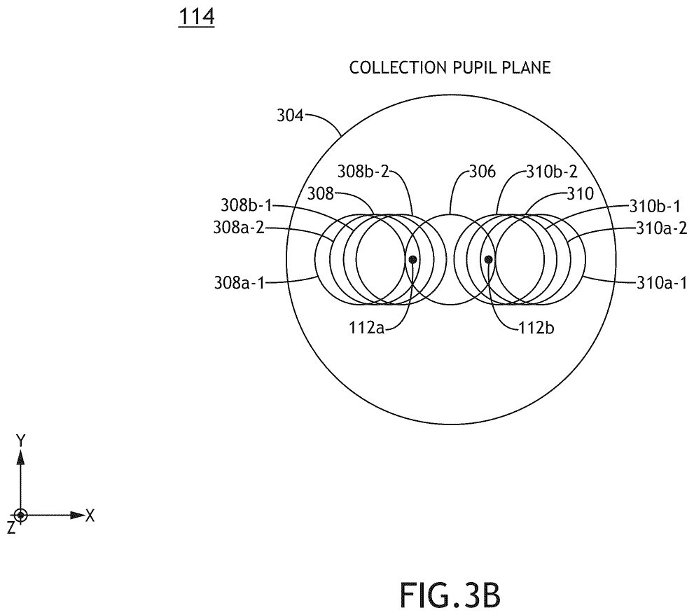

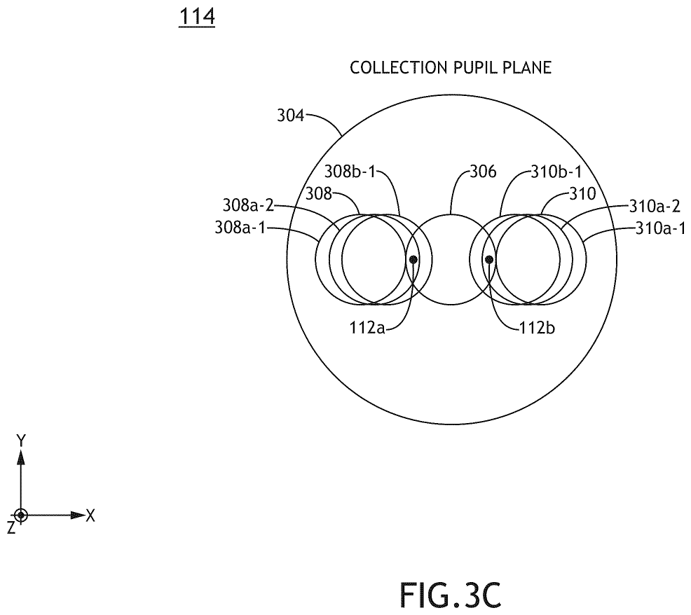

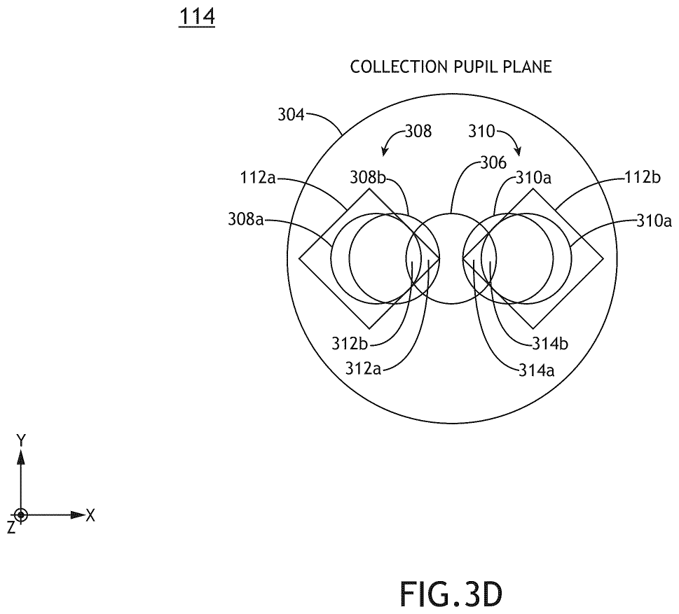

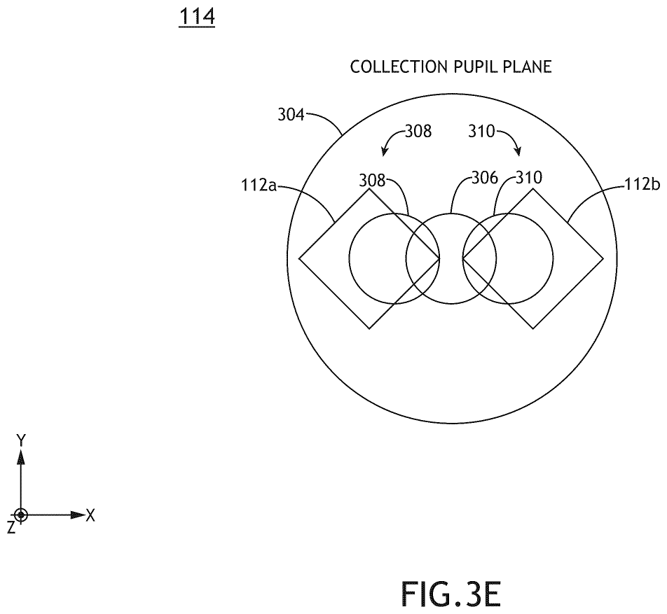

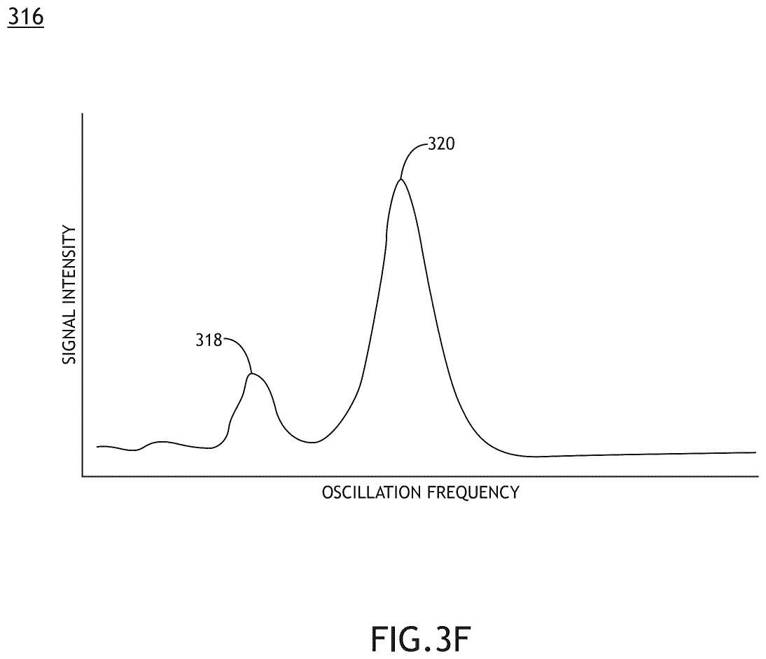

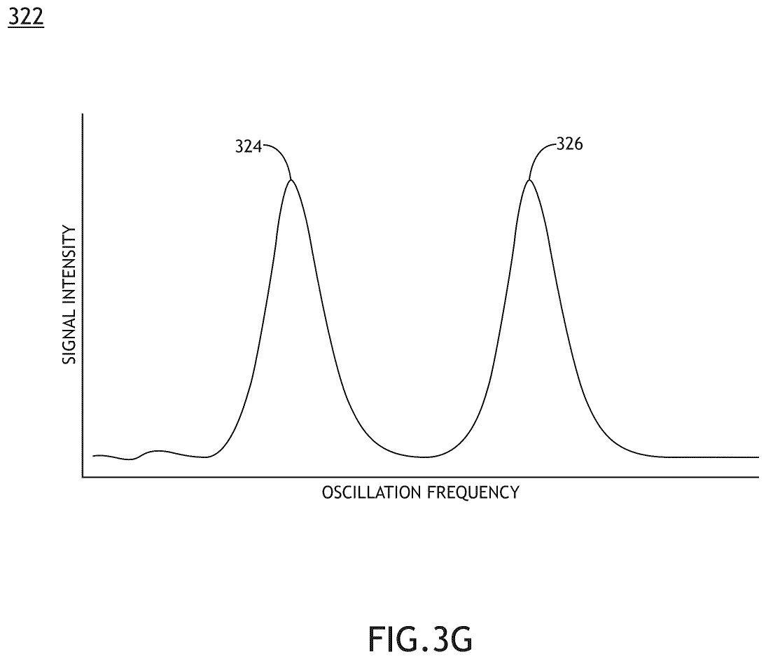

Referring now to FIGS. 2-3E, the collection of diffraction orders from grating-over-grating structures and the placement of the photodetectors 112 for scanning scatterometry overlay metrology is described in greater detail, in accordance with one or more embodiments of the present disclosure.

FIG. 2 illustrates a conceptual view of one or more cells 202, in accordance with one or more embodiments of the present disclosure.

In embodiments, the overlay target 204 includes one or more cells 202, where any particular cell 202 of the one or more cells 202 may include a grating-over-grating structure 206 with a periodicity along any direction. For example, the overlay target 204 may include a plurality of cells 202, where the different cells 202 have different configurations of the periodicities of the associated gratings. For instance, the overlay target 204 may include a grating-over-grating structure 206 in each cell having periodicity along a common direction. By way of another example, the overlay target 204 may include a single cell 202 with a grating-over-grating structure 206 having periodicity along a common direction.

In embodiments, the grating-over-grating structure 206 may include a first-layer grating feature 208 (e.g., top grating feature) located on a first layer 210 (e.g., top layer) of the sample and a second-layer grating feature 212 (e.g., bottom grating feature) located on a second layer 214 (e.g., bottom layer) of the sample 104, where the first-layer grating feature 208 and the second-layer grating feature 212 are arranged along the scan direction. For instance, the second-layer grating feature 212 may be arranged adjacent to the first-layer grating feature 208, such that the first-layer grating feature 208 at least partially overlaps with the second-layer grating feature 212.

In embodiments, the grating-over-grating structure 206 may further include an intermediate-layer grating feature (not shown) located on an intermediate layer between at least the first layer 210 and the second layer 214.

In embodiments, the gratings of the grating-over-grating structure 206 may have different pitches. For example, the first-layer grating feature 208 and the second-layer grating feature 212 may have different pitches. In a non-limiting example, the first-layer grating feature 208 may have a pitch P₁ that is smaller than a pitch P₂ of the second-layer grating feature 212.

In embodiments, the gratings of the grating-over-grating structure 206 may be formed of different materials. For example, the first-layer grating feature 208 may be formed of a first material and at least one of the intermediate-layer grating feature or the second-layer grating feature 212 may be formed of a second material, where the first material is different than the second material. In some instances, the first material of the first-layer grating feature 208 may absorb the second wavelength of the second illumination beam. In additional instances, at least one of the intermediate-layer grating feature of the second-layer grating feature 212 may absorb the first wavelength of the first illumination beam.

It is noted that the configuration depicted in FIG. 2 is provided merely for illustrative purposes and shall not be construed as limiting the scope of the present disclosure. As such, the grating-over-grating structure 206 may be formed of any number of layers with any variety of pitches. Further, the overlay target 204 may include any number of cells 202 suitable for measurement. Additionally, the cells 202 may be distributed in any pattern or arrangement. In embodiments, the overlay target 204 includes one or more cell groupings distributed along a scanning direction (e.g., a direction of motion of the sample 104), where cells 202 within each particular cell grouping are oriented to have grating-over-grating structures 206 with periodicity along a common direction. In this way, all cells 202 within a particular cell grouping may be imaged at the same time while the sample 104 is scanned through a measurement field of view of the collection sub-system 110.

Referring now to FIGS. 3A-3E, various non-limiting configurations for the generation and measurement of time-varying interference signals from a grating-over-grating structure 206 in one or more cells 202 of an overlay target 204 are described in accordance with one or more embodiments of the present disclosure.

FIG. 3A illustrates a top view of an illumination pupil 302 in an illumination pupil plane 120 of the overlay metrology sub-system 102, in accordance with one or more embodiments of the present disclosure. For example, the illumination pupil plane 120 may correspond to a pupil plane in the illumination sub-system 106 as illustrated in FIG. 1B. In embodiments, the illumination sub-system 106 illuminates the overlay target 204 with overlapping illumination beams 108a,b at normal incidence (or near-normal incidence) as illustrated in FIG. 3A. Further, the overlapping illumination beams 108a,b may illuminate the overlay target 204 with a limited range of incidence angles as illustrated by the limited size in the collection pupil plane 114. In this regard, the overlay target 204 may diffract the two or more illumination beams 108a,b into one or more discrete diffraction orders.

FIGS. 3B-3E illustrate non-limiting configurations for capturing time-varying interference signals from an overlay target 204 with a grating-over-grating structure 206 in a scanning configuration.

FIG. 3B illustrates a non-limiting configuration of diffraction orders of the illumination beams 108a,b, associated with the overlay metrology target shown in FIG. 2, in a collection pupil plane 114 and associated positions of photodetectors 112 suitable for capturing time-varying interference signals from which an overlay measurement may be extracted. In particular, FIG. 3B illustrates 0-order grating diffraction 306, −1 order grating diffraction 308 for each illumination beam, and +1 order grating diffraction 310 for each illumination beam distributed along the direction of periodicity of the overlay target 204 (e.g., the X direction here) in the collection pupil plane 114.

For example, FIG. 3B illustrates a −1 order grating diffraction lobe 308a-1 associated with the first illumination beam 108a (e.g., having a high wavelength Δ₁) for the first-layer grating feature 208 (e.g., having a low pitch P₁), a −1 order grating diffraction lobe 308a-2 for the first illumination beam 108a (e.g., having a high wavelength Δ₁) for the second-layer grating feature 212 (e.g., having a high pitch P₂), a −1 order grating diffraction lobe 308b-1 associated with the second illumination beam 108b (e.g., having a low wavelength Δ₂) for the first-layer grating feature 208 (e.g., having a low pitch P₁), and a −1 order grating diffraction lobe 308b-2 associated with the second illumination beam 108b (e.g., having a low wavelength Δ₂) for the second-layer grating feature 212 (e.g., having a high pitch P₂). By way of another example, FIG. 3B illustrates a +1 order grating diffraction lobe 310a-1 associated with the first illumination beam 108a (e.g., having a high wavelength Δ₁) for the first-layer grating feature 208 (e.g., having a low pitch P₁), a +1 order grating diffraction lobe 310a-2 associated with the first illumination beam 108a (e.g., having a high wavelength Δ₁) for the second-layer grating feature 212 (e.g., having a high pitch P₂), a +1 order grating diffraction lobe 310b-1 associated with the second illumination beam 108b (e.g., having a low wavelength Δ₂) for the first-layer grating feature 208 (e.g., having a low pitch P₁), and a +1 order grating diffraction lobe 310b-2 associated with the second illumination beam 108b (e.g., having a low wavelength Δ₂) for the second-layer grating feature 212 (e.g., having a high pitch P₂). In this regard, as shown in FIG. 3B, if each grating feature 208, 212 of the grating-over-grating structure 206 diffracts both the first illumination beam 108a and the second illumination beam 108b, the collection pupil plane 114 may include eight non-zero-order diffraction lobes 308a-1-310b-2 associated with first-order grating diffraction 308,310. In other words, the wavelengths of both illumination beams 108a,b may interact with both grating features 208, 212 of the grating-over-grating structure 206. In this example, a respective pitch may be selected to prevent the interaction of one or more selected diffraction lobes from reaching the photodetectors 112a,b. In this regard, the photodetector may not detect (or capture) the associated diffraction order from the respective grating feature associated with the unwanted signal. Further, in embodiments, the intensity of the illumination beams may be adjusted to make the two time-varying interference signals uniform.

It is contemplated that one or more of the diffraction lobes 108a-1-310b-2 for the first-order grating diffraction 308, 310 may not be present if at least one of the first-layer grating feature 208 or the second-layer grating feature 212 absorb at least one of the first illumination beam 108a or the second illumination beam 108b. For example, FIG. 3C depicts a non-limiting configuration of diffraction orders of the two illumination beams 108a,b associated with the overlay metrology target shown in FIG. 2, in a collection pupil plane 114 and associated positions of photodetectors 112 suitable for capturing time-varying interference signals from which an overlay measurement may be extracted. In particular, FIG. 3C depicts a non-limiting example where the second-layer grating feature 212 absorbs the second illumination beam 108b. For example, in a non-limiting example, the first-layer grating feature 208 may be formed of a thin extreme UV (EUV) resist material (e.g., having a thickness between about 10-12 nm) and the second-layer grating feature 212 may be formed of an opaque material such as, but not limited to, polysilicon. In this example, the first illumination beam 108a may have a wavelength Δ₁ of approximately 550 nm and the second illumination beam 108b may have a wavelength Δ₂ between approximately 400-450 nm. As such, the polysilicon material of the second-layer grating feature 212 may absorb the wavelength Δ₂ of the second illumination beam 108b. In this regard, as shown in FIG. 3C, the −1 order grating diffraction lobe 308b-2 and the +1 order grating diffraction lobe 310b-2 may not be present, such that the collection pupil plane 114 may include only six diffraction lobes associated with first-order grating diffraction (rather the eight as shown in FIG. 3B).

Although FIG. 3C depicts a non-limiting example where the second-layer grating feature 212 absorbs the second illumination beam 108b, it is contemplated herein that the first-layer grating feature 208 may alternatively (or additionally) absorb the first illumination beam 108a due the respective absorption of the material of the first-layer grating feature 208. As such, FIG. 3C is provided merely for illustrative purposes and shall not be construed as limiting the scope of the present disclosure, rather either grating-layer feature may absorb either illumination beam.

FIGS. 3B-3C further illustrate overlap between the θ-order grating diffraction 306 and at least some of the first-order grating diffractions 308, 310 to capture respective time-varying interference signals by the two or more photodetectors 112a,b.

In particular, FIG. 3B illustrates overlap between the θ-order grating diffraction 306 and −1 order grating diffraction lobes 308a-2, 308b-1, 308b-2, where the −1 order grating diffraction lobe 308a-1 only overlaps with the −1 order grating diffraction lobes 308a-2, 308b-1, 308b-2 (e.g., not the θ-order grating diffraction 306). Further, FIG. 3B illustrates overlap between the θ-order grating diffraction 306 and +1 order grating diffraction lobes 310a-2, 310b-1, 310b-2, where the +1 order grating diffraction lobe 310a-1 only overlaps with the +1 order grating diffraction lobes 310a-2, 310b-1, 310b-2 (e.g., not the θ-order grating diffraction 306). In this regard, time-varying interference signals of the first illumination beam 108a from the second-layer grating feature 212, second illumination beam 108b from the first-layer grating feature 208, and second illumination beam 108b from the first-layer grating feature 212 are captured by the two or more photodetectors 112a,b.

FIG. 3C illustrates overlap between the θ-order grating diffraction 306 and the −1 order grating diffraction lobes 308a-2, 308b-1, where the −1 order grating diffraction lobe 308a-1 only overlaps with the −1 order grating diffraction lobes 308a-2 and 308b-1 (e.g., not the θ-order grating diffraction 306). Further, FIG. 3C illustrates overlap between the θ-order grating diffraction 306 and the +1 order grating diffraction lobes 310a-2, 310b-1, where the +1 order grating diffraction lobe 310a-1 only overlaps with the +1 order grating diffraction lobes 310a-2 and 310b-1 (e.g., not the θ-order grating diffraction 306). In this regard, time-varying interference signals of the first illumination beam 108a from the second-layer grating feature 212 and second illumination beam 108b from the first-layer grating feature 208 are captured by the two or more photodetectors 112a,b.

Referring generally to FIGS. 3B-3C, it is contemplated herein that the phase of each of the grating diffraction orders (e.g., the first-order diffraction 308,310) may oscillate during a scan to form the time-varying interference signals and overlay may be determined based on these oscillations. As a result, an overlay measurement may be performed by capturing and comparing these time-varying interference patterns. For example, the phase differences of the −1 order and +1 order grating diffraction 308, 310 from each individual grating feature 208, 212 of the grating-over-grating structure 206 may be used to measure the position of the grating relative to the optical system 100, as shown and described by Equations 2.1-2.2 below:

$${I}_{P 1 \pm 1} = {( {E}_{0} + {E}_{1} )}^{2} = {E}_{0}^{2} + {E}_{1}^{2} + 2 {E}_{0} {E}_{1} = D C + 2 {A}_{\pm 1} {A}_{0} cos [ \frac{2 π}{{P}_{1}} ( X - {X}_{0} ) \pm φ ] \qquad ( 2.1 )$$

$${I}_{P 2 \pm 1} = {( {E}_{0} + {E}_{1} )}^{2} = {E}_{0}^{2} + {E}_{1}^{2} + 2 {E}_{0} {E}_{1} = D C + 2 {A}_{\pm 1} {A}_{0} cos [ \frac{2 π}{{P}_{2}} ( X - {X}_{0} ) \pm θ ] \qquad ( 2.2 )$$

where I_{P1±1} is the intensity of the interference signals in the overlap region of the θ-order and first-order signals, respectively, for the first-layer grating feature 208, I_{P2±1} is the intensity of the interference signals in the overlap region of the θ-order and first-order signals, respectively, for the second-layer grating feature 212, E₀ is the electric field amplitude at θ-order diffraction lobe, E₁ is the electric field amplitude at first-order diffraction lobe, A_{±1} is the amplitude of the first-order signal, A₀ is the amplitude of the 0-order signal, X₀ is the grating starting position, X is the scanning position, φ is the optical path difference (OPD) for the first-layer grating feature, θ is the optical path difference (OPD) for the second-layer grating feature, P₁ is pitch of the first-layer grating feature, and P₂ is pitch of the second-layer grating feature.

The intensity of the time-varying interference signals for the first-layer grating feature 208, I_{P1±1}, may be based on the second illumination beam 108b having the wavelength Δ₂. For example, as shown in FIG. 3B, I_{P1±1} may be based on the θ-order diffraction lobe 306 overlapping with the first-order diffraction lobes 308b-1, 310b-1. By way of another example, as shown in FIG. 3C, I_{P1±1} may be based on the θ-order diffraction lobe 306 overlapping with the first-order diffraction lobes 308b-1, 310b-1.

The intensity of the time-varying interference signals for the second-layer grating feature 212, I_{P2±1}, may be based on the first illumination beam 108a having the wavelength Δ₁. For example, as shown in FIG. 3B, I_{P2±1} may be based on the θ-order diffraction lobe 306 overlapping with the first-order diffraction lobes 308a-2, 310a-2 and/or first-order diffraction lobes 308b-2, 310b-2. By way of another example, as shown in FIG. 3C, I_{P2±1} may be based on the θ-order diffraction lobe 306 overlapping with the first-order diffraction lobes 308a-2, 310a-2, where the first-order diffraction lobes 308b-2, 310b-2 are not present due the absorption of the second illumination beam (having the wavelength Δ₂) by the second-layer grating feature 212.

In embodiments, the overlay error between the one or more sample layers associated with the grating-over-grating structures 206 may be determined based on Equation 3, as shown and described by:

$$O V L = \frac{1}{4 π} ( {P}_{1} ( {ϕ}_{1 , 1} + {ϕ}_{1 , - 1} ) - {P}_{2} ( {ϕ}_{2 , 1} + {ϕ}_{2 , - 1} ) ) \qquad ( 3 )$$

In embodiments, the wavelengths of the illumination beams are selected based on one or more properties of the time-varying interference signals, which may in turn depend on material properties of the sample. For example, the first wavelength Δ₁ of the first illumination beam 108a may selected based on one or more properties of the time-varying interference signals of the first-layer grating feature 208. By way of another example, the second wavelength Δ₂ of the second illumination beam 108b may be selected based on one or more properties of the time-varying interference signals of the second-layer grating feature 212. The one or more properties of the time-varying interference signals may be contrast (e.g., a peak to valley amplitude, A_{±1}A₀, of a time-varying interference signal associated with a selected diffraction order overlapped with the θ-order diffraction), where a selected contrast level is achieved by selecting the wavelengths of the respective illumination beams. For example, the one or more properties of the time-varying interference signals of the first-layer grating feature 208 include a contrast above a selected threshold. By way of another example, the one or more properties of the time-varying interference signals of the second-layer grating feature 212 include a contrast above a selected threshold. In a non-limiting example, a thin EUV resist material of the first-layer grating feature 208 may require a short wavelength for contrast. In this regard, the first wavelength Δ₁ of the first illumination beam 108a may be selected (e.g., wavelength between 400-450 nm) to achieve the selected contrast level.

FIGS. 3D-3E illustrate the location of the two or more photodetectors 112a,b, in accordance with one or more embodiments of the present disclosure. It is contemplated herein that photodetectors 112 placed at locations in the collection pupil plane 114 associated with diffraction lobes (e.g., areas at which first-order diffraction lobes may overlap with θ-order diffraction lobes) may capture time-varying interference signals indicative of overlay.

FIG. 3D illustrates a non-limiting configuration of diffraction orders of the illumination beam 108a,b associated with the overlay metrology target shown in FIG. 2, in a collection pupil plane 114 and associated positions of photodetectors 112 suitable for capturing time-varying interference signals from which an overlay measurement may be extracted. For purposes of simplicity, −1 order grating diffraction 308a,b and +1 order grating diffraction 310a,b is shown for only one illumination beam. In particular, FIG. 3D illustrates θ-order diffraction 306, −1 order grating diffraction 308a,b for each grating feature 208, 212, and +1 order grating diffraction 310a,b for each grating feature 208, 212 distributed along the direction of periodicity of the grating-over-grating structure 206 (e.g., the X direction here) in the collection pupil plane 114, where each first-order grating diffraction 308a,b, 310a,b overlaps with the θ-order diffraction 306. The first photodetector 112a may be placed at a location in the collection pupil plane 114 associated with −1 order grating diffraction 308a from the first-layer grating feature 208 and −1 order grating diffraction 308b from the second-layer grating feature 212 for each illumination beam 108a,b. The second photodetector 112b may be placed at a location in the collection pupil plane 114 associated with +1 order grating diffraction 310a from the first-layer grating feature 208 and +1 order grating diffraction 310b from the second-layer grating feature 212 for each illumination beam 108a,b. In this regard, the first photodetector 112a may capture time-varying interference signals associated with the −1 order grating diffraction 308b overlapping with the θ-order grating diffraction 306 and −1 order grating diffraction 308a overlapping with the θ-order grating diffraction 306 and the second photodetector 112b may capture time-varying interference signals associated with the +1 order grating diffraction 310b overlapping with the θ-order grating diffraction 306 and +1 order grating diffraction 310a overlapping with the θ-order grating diffraction 306.

Additionally, FIG. 3D may illustrate a non-limiting configuration of diffraction orders where each grating feature 208, 212 absorbs a respective illumination beam, as discussed previously herein.

FIG. 3E illustrates a non-limiting configuration of diffraction orders of the illumination beam 108a,b associated with the overlay metrology target shown in FIG. 2, in a collection pupil plane 114 and associated positions of photodetectors 112 suitable for capturing time-varying interference signals from which an overlay measurement may be extracted. In particular, FIG. 3E illustrates θ-order diffraction 306, −1 order grating diffraction 308 for each illumination beam, and +1 order grating diffraction 310 for each illumination beam distributed along the direction of periodicity of the grating-over-grating structure 206 (e.g., the X direction here) in the collection pupil plane 114, where the +1 order grating diffraction and −1 order grating diffraction for each illumination beam and each grating-layer feature 208, 212 fully overlaps. For example, the −1 order grating diffraction 308 and the +1 order grating diffraction 310 may be associated with grating diffraction from first-layer grating feature 208 and the second-layer grating feature 212 (which are fully overlapping) and the −1 order grating diffraction 308 and the +1 order grating diffraction 310 may be associated with grating diffraction from first-layer grating feature 208 and the second-layer grating feature 212 (which are fully overlapping), where the diffraction angles are based on the pitches of the gratings and illumination wavelength. In this regard, the respective diffraction lobes of the +1 order grating diffraction 308 from the respective layers 210, 214 may overlap each other and the −1 order grating diffraction 310 from the respective layers 210, 214 may fully overlap, where the first-order grating diffraction from each overlaps with the θ-order grating diffraction.

In other words, the ratio of the first wavelength of the first illumination beam to the first pitch of the first-layer grating feature may be equal to the ratio of the second wavelength of the second illumination beam to the second pitch of the second-layer grating feature, as shown by Equation 1 below:

$$\frac{{λ}_{1}}{{P}_{1}} = \frac{{λ}_{2}}{{P}_{2}} \qquad ( 1 )$$

In this regard, a respective wavelength and/or pitch of a respective grating of the grating-over-grating structure may be adjusted such that the associated diffraction angle is equal to achieve the full overlap between the associated diffraction orders. Additionally, a respective wavelength and/or pitch of a respective grating of the grating-over-grating structure may be adjusted such that the associated diffraction angle is adjusted to cause the respective diffraction lobe to not overlap with the θ-order diffraction lobe. For example, as shown in FIGS. 3B-3C, the diffraction lobes 308a-1, 310a-1 are shifted such that they do not overlap with the θ-order diffraction and are thus not used when calculating I_{P1±1}, I_{P2±1}, as discussed above with respect to Equations 2.1-2.2 above.

Referring to FIG. 3E, the first photodetector 112a may be placed at a location in the collection pupil plane 114 associated with the fully overlapping −1 order grating diffraction 308 from the first-layer grating feature 208 and the second-layer grating feature 212 for each illumination beam 108a,b. The second photodetector 112b may be placed at a location in the collection pupil plane 114 associated with the fully overlapping +1 order grating diffraction 310 from the first-layer grating feature 208 and the second-layer grating feature 212 for each illumination beam 108a,b. In this regard, the first photodetector 112a may capture time-varying interference signals associated with the −1 order grating diffraction 308b overlapping with the θ-order grating diffraction 306 and −1 order grating diffraction 308a overlapping with the θ-order grating diffraction 306 and the second photodetector 112b may capture time-varying interference signals associated with the +1 order grating diffraction 310b overlapping with the θ-order grating diffraction 306 and +1 order grating diffraction 310a overlapping with the θ-order grating diffraction 306.

It is recognized herein that the distribution of diffracted orders of an illumination beam 108 by a periodic structure such as a grating-over-grating structure 206 may be influenced by a variety of parameters such as, but not limited to, a wavelength of the illumination beam 108, an incidence angle of the illumination beam 108 in both altitude and azimuth directions, pitches of the gratings of the grating-over-grating structure 206, or a numerical aperture (NA) of a collection lens. Accordingly, in embodiments of the present disclosure, the illumination sub-system 106, the collection sub-system 110, and the overlay target 204 may be configured (e.g., according to a metrology recipe defining a selected set of associated parameters) to provide a desired distribution of diffraction orders in a collection pupil plane 114 suitable for generating time-varying interference patterns indicative of overlay. For example, the illumination sub-system 106 and/or the collection sub-system 110 may be configured to generate measurements on grating-over-grating structures having selected range of periodicities to provide a desired distribution in the collection pupil plane 114. Further, various components of the illumination sub-system 106 and/or the collection sub-system 110 (e.g., stops, pupils, or the like) may be adjustable to provide the desired distribution in the collection pupil plane 114.

It is to be understood, however, that the particular configurations illustrated in FIGS. 3B-3E and the associated descriptions are not limiting. In particular, it is contemplated herein that the time-varying interference signals may be captured using various metrology overlay techniques, as generally discussed in U.S. Pat. No. 11,300,405 issued on Apr. 12, 2022; U.S. Pat. No. 11,378,394, issued on Jul. 5, 2022; U.S. Patent Publication No. 2023/0314319, published on Oct. 5, 2023; U.S. Pat. No. 11,796,925, issued on Oct. 24, 2023; U.S. patent application Ser. No. 18/099,798, filed on Jan. 20, 2023; U.S. patent application Ser. No. 18/110,746, filed on Feb. 16, 2023; U.S. patent application Ser. No. 18/230,542, filed on Aug. 4, 2023; U.S. patent application Ser. No. 18/372,444, filed on Sep. 25, 2023; and U.S. patent application Ser. No. 18/372,531, filed on Sep. 25, 2023, which are all incorporated herein by reference in their entireties.

It is contemplated herein that existing systems utilizing a single wavelength illumination beam may produce weak signals. For example, FIG. 3F depicts a plot 316 of time-varying signals shown in frequency space for a single wavelength system. As shown in FIG. 3F, the intensity 318 of the time-varying interface signal associated with the bottom grating is much weaker than the intensity 320 of the time-varying interference signal associated with the top grating.

Conversely, the system 100 of the present disclosure utilizes multiple wavelength illumination beams that produce strong signals. For example, FIG. 3G depicts a plot 322 of time-varying signals shown in frequency space for a multiple wavelength system 100. As shown in FIG. 3G, the intensity 324 of the time-varying interference signal associated with the second-layer grating feature 212 and the intensity 326 of the time-varying interference signal associated with the first-layer grating feature 208 may be substantially equal. As previously discussed herein, the intensity of illumination beam 108 may be adjusted to control the intensity of the time-varying interference signals from each of the first-layer grating feature 208 and the second-layer grating feature 212, such that the intensity of the respective time-varying interference signals is substantially equal (e.g., equal within a selected tolerance). In this regard, the equaling of the time-varying signal intensity may improve accuracy.

It is contemplated herein that for purposes of simplicity, the plots shown in FIG. 3F-3G depict time-varying interference signals for only one of the one or more photodetectors.

Referring again to FIGS. 1A-1B, additional components of the overlay metrology sub-system 102 are described in greater detail in accordance with one or more embodiments of the present disclosure.

In embodiments, the overlay metrology system 100 includes a controller 122 communicatively coupled to the overlay metrology sub-system 102. The controller 122 may include one or more processors 124 and a memory device 126, or memory. For example, the one or more processors 124 may be configured to execute a set of program instructions maintained in the memory device 126.

In embodiments, the controller 122 may execute any of various processing steps associated with overlay metrology. For example, the controller 122 may be configured to generate control signals to direct or otherwise control the overlay metrology sub-system 102, or any components thereof. For instance, the controller 122 may be configured to direct the translation stage 116 to translate the sample 104 along one or more measurement paths, or swaths, to scan one or more overlay targets through a measurement field of view of the overlay metrology sub-system 102 and/or direct the beam-scanning sub-system 118 to position or scan one or more modified illumination beams on the sample 104. By way of another example, the controller 122 may be configured to receive signals corresponding to the time-varying interference signals from the photodetectors 112. By way of another example, the controller 122 may generate correctables for one or more additional fabrication sub-systems as feedback and/or feed-forward control of the one or more additional fabrication sub-systems based on overlay measurements from the overlay metrology sub-system 102.

The one or more illumination sources 128 may include any type of illumination source suitable for providing two or more illumination beams 108 having different wavelengths. In embodiments, the one or more illumination sources 128 include one or more laser sources. For example, the one or more illumination sources 128 may include, but is not limited to, one or more narrowband laser sources, a broadband laser source, a supercontinuum laser source, a white light laser source, or the like. In this regard, the one or more illumination sources 128 may provide two or more illumination beams 108 having high coherence (e.g., high spatial coherence and/or temporal coherence). In embodiments, the one or more illumination sources 128 include one or more laser-sustained plasma (LSP) sources. For example, the one or more illumination sources 128 may include, but is not limited to, an LSP lamp, an LSP bulb, or an LSP chamber suitable for containing one or more elements that, when excited by a laser source into a plasma state, may emit broadband illumination.

In embodiments, the illumination sub-system 106 includes one or more optical components suitable for modifying and/or conditioning the illumination beam 108 as well as directing the illumination beam 108 to the sample 104. For example, the illumination sub-system 106 may include one or more illumination lenses 130 (e.g., to collimate the illumination beam 108, to relay an illumination pupil plane 120 and/or an illumination field plane 132, or the like). In embodiments, the illumination sub-system 106 includes one or more illumination control optics 134 to shape or otherwise control the illumination beam 108. For example, the illumination control optics 134 may include, but are not limited to, one or more apodizers, one or more field stops, one or more pupil stops, one or more polarizers, one or more filters, one or more beam splitters, one or more diffusers, one or more homogenizers, one or more beam shapers, or one or more mirrors (e.g., static mirrors, translatable mirrors, scanning mirrors, or the like).

In embodiments, the one or more optical components of the illumination sub-system 106 may be configured to cause the two or more illumination beams 108a,b to overlap. For example, the one or more illumination optics may be configured to align the first illumination beam 108a and the second illumination beam 108b such that they overlap. In this regard, the two or more illumination beams 108a,b may hit the grating-over-grating structure 206 of the overlay target 204 at the same time and with the same angle. Further, the spot size of the illumination beams 108a,b may be the same when overlapped.

In embodiments, the overlay metrology sub-system 102 includes an objective lens 136 to focus the illumination beam 108 onto the sample 104 (e.g., an overlay target with overlay target elements located on two or more layers of the sample 104).

The two or more illumination beams 108 may be, but are not required to be, incident on different portions of the sample 104 (e.g., different cells of an overlay target) within a measurement field of view (e.g., a field of view of the objective lens 136).

In embodiments, the controller 122 captures the interference signals detected by the photodetectors 112. For example, the controller 122 may generally capture data such as, but not limited to, the phases of the time-varying interference signals using any technique known in the art such as, but not limited to, frequency-domain analysis (e.g., FFT), one or more phase-locked loops, and the like. Further, the controller 122 may capture the interference signals, or any data associated with the interference signals, using any combination of hardware (e.g., circuitry) or software techniques.

In embodiments, the controller 122 determines an overlay measurement between layers of the overlay target along the measurement direction based on the comparison of the interference signals. For example, the controller 122 may determine an overlay measurement based on the phases of the interference signals. For instance, U.S. Pat. No. 10,824,079, issued on Nov. 3, 2020, which is incorporated by reference in the entirety, generally describes the electric field of diffracted orders in a collection pupil and further provides specific relationships between overlay and measured intensity in the pupil plane. It is contemplated herein that the systems and methods disclosed herein may extend the teachings of U.S. Pat. No. 10,824,079 to time-varying interference signals captured by photodetectors placed in overlap regions between 0 and +/−1 diffraction orders. In particular, it is contemplated herein that overlay on a sample may be proportional to the relative phase shift between the two time-varying interference signals.

Further, the controller 122 may calibrate or otherwise modify the overlay measurement based on known, assumed, or measured features of the sample that may also impact the time-varying interference signals such as, but not limited to, sidewall angles or other sample asymmetries.

In embodiments, the collection sub-system 110 includes at least two photodetectors 112 (e.g., photodetectors 112a,b) located at a collection pupil plane 114 configured to capture light from the sample 104 (e.g., collected light 138), where the collected light 138 includes at least the θ-order diffraction 306, the −1 order diffraction 308, and the +1 order diffraction 310 from the first illumination beam and the second illumination beam, as illustrated in FIG. 3C. The collection sub-system 110 may include one or more optical elements suitable for modifying and/or conditioning the collected light 138 from the sample 104. In embodiments, the collection sub-system 110 includes one or more collection lenses 140 (e.g., to collimate the illumination beam 108, to relay pupil and/or field planes, or the like), which may include, but are not required to include, the objective lens 136. In embodiments, the collection sub-system 110 includes one or more collection control optics 142 to shape or otherwise control the collected light 138. For example, the collection control optics 142 may include, but are not limited to, one or more field stops, one or more pupil stops, one or more polarizers, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

In embodiments, the collection sub-system 110 includes two or more collection channels 144, each with a separate pair of photodetectors 112. For example, the overlay metrology sub-system 102 may include one or more beamsplitters 146 arranged to split the collected light 138 into the collection channels 144. Further, the beamsplitters 146 may be polarizing beamsplitters, non-polarizing beamsplitters, or a combination thereof. It is to be understood, however, that the illustration of one collection channel 144 in FIG. 1B is provided solely for illustrative purposes and should not be interpreted as limiting. For example, the collection sub-system 110 may include multiple collection channels 144 or a single collection channel 144.

In embodiments, multiple collection channels 144 are configured to collect light from multiple illumination beams 108 on the sample 104. For example, in the case that an overlay target 204 has one or more cells 202 distributed in a direction different than a scan direction, the overlay metrology sub-system 102 may simultaneously illuminate the different cells 202 with different illumination beams 108 and simultaneously capture interference signals associated with each illumination beam 108. Additionally, in embodiments, multiple illumination beams 108 directed to the sample 104 may have different polarizations. In this way, the diffraction orders associated with each of the illumination beams 108 may be separated. For example, polarizing beamsplitters 146 may efficiently separate the diffraction orders associated with the different illumination beams 108. By way of another example, polarizers may be used in one or more collection channels 144 to isolate desired diffraction orders for measurement.

In embodiments, the overlay metrology sub-system 102 includes a beam-scanning sub-system 118 to position, scan, or modulate positions of one or more illumination beams 108 on the sample 104 during measurement.

The beam-scanning sub-system 118 may include any type or combination of elements suitable for scanning positions of one or more illumination beams 108. In embodiments, the beam-scanning sub-system 118 includes one or more deflectors suitable for modifying a direction of an illumination beam 108. For example, a deflector may include, but is not limited to, a rotatable mirror (e.g., a mirror with adjustable tip and/or tilt). Further, the rotatable mirror may be actuated using any technique known in the art. For example, the deflector may include, but is not limited to, a galvanometer, a piezo-electric mirror, or a micro-electro-mechanical system (MEMS) device. By way of another example, the beam-scanning sub-system 118 may include an electro-optic modulator, an acousto-optic modulator, or the like.

The deflectors may further be positioned at any suitable location in the overlay metrology sub-system 102. In embodiments, one or more deflectors are placed at one or more pupil planes common to both the illumination sub-system 106 and the collection sub-system 110. In this regard, the beam-scanning sub-system 118 may be a pupil-plane beam scanner and the associated deflectors may modify the positions of one or more illumination beams 108 on the sample 104 without impacting positions of diffraction orders in the collection pupil plane 114. Further, a distribution of one or more illumination beams 108 in an illumination field plane 132 may further be stable as the beam-scanning sub-system 118 modifies positions of the one or more illumination beams 108 on the sample 104. Pupil-plane beam scanning is described generally in U.S. Pat. No. 11,300,524, issued on Apr. 12, 2022, which is incorporated by reference in its entirety.

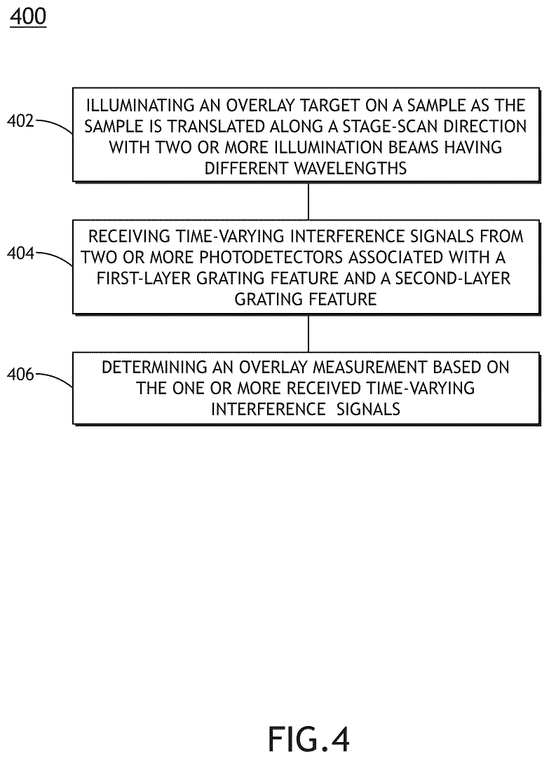

FIG. 4 is a flow diagram illustrating steps performed in a method 400 for scanning overlay metrology of overlay targets using multiple wavelengths, in accordance with one or more embodiments of the present disclosure. Applicant notes that the embodiments and enabling technologies described previously herein in the context of the overlay metrology system 100 should be interpreted to extend to the method 400. It is further noted, however, that the method 400 is not limited to the architecture of the overlay metrology system 100.

In a step 402, one or more cells of an overlay target are illuminated. For example, the one or more cells 202 of the overlay target 204 on the sample 104 are illuminated as the sample 104 is scanned with respect to the illumination. For instance, the one or more cells 202 of the overlay target 204 on the sample 104 are illuminated with at least a first illumination beam having a first wavelength and a second illumination beam having a second wavelength, where the first wavelength is different than the second wavelength. In some cases, the first illumination beam and the second illumination beam be aligned to overlap with each other.

In a step 404, time-varying interference signals from one or more photodetectors 112a,b may be collected. For example, time-varying interference signals based on at least one diffraction order of the first illumination beam from the first-layer grating feature 208 and at least one diffraction order of the second illumination beam from the second-layer grating feature 212 may be collected by the one or more photodetectors 112a,b.

The time-varying interference signals from the two photodetectors 112a,b may be placed in regions of the collection pupil associated with overlapping diffraction from the gratings in the grating-over-grating structures 206. For example, the photodetectors 112a,b may be placed in regions of the collection pupil associated with the at least one diffraction order of the first illumination beam and the at least one diffraction order of the second illumination beam. For instance, the photodetectors 112a,b may be placed such that they capture first-order diffraction signals from the first illumination beam overlapping with the θ-order diffraction, first-order diffraction signals from the second illumination beam overlapping with the θ-order diffraction, and in some cases, overlapping first-order diffractions signals from both the first illumination beam and the second illumination beam. In this regard, while the illumination beam 108 scans over the multi-layer overlay target 204, the first-order signals and the θ-order signals may form time-varying interference signals described herein, where the overlapping area between the θ-order signals and the first-order signals may oscillate as a function of illumination spot location, in accordance with Equations 2.1-2.2 discussed previously herein.

In a step 406, an overlay measurement between the one or more sample layers associated with the grating-over-grating structures may be determined, in accordance with Equations 2.1-3 shown and described above. For example, the overlay measurement between sample layers associated with the grating-over-grating structures in the one or more cells 202 of the overlay target 204 are determined based on the signals from the two photodetectors 112a,b. For instance, an overlay measurement along a direction of periodicity of the grating-over-grating structures 206 may be proportional to a phase difference between the time-varying interference signals from the two photodetectors. The phase difference may be determined using any technique known in the art including, but not limited to, frequency-domain analysis techniques (e.g., Fast Fourier Transform, or the like) applied to the two time-varying interference signals. Further, in embodiments, overlay measurements of the sample along a particular measurement direction may be generated based on data from multiple cells of the overlay target with grating-over-grating structures having periodicity along the particular measurement direction.

It is contemplated herein that the method 700 may be applied to a wide variety of overlay target designs suitable for 1 D or 2D metrology measurements.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An overlay metrology system comprising:
an illumination sub-system comprising:
one or more illumination sources configured to generate two or more illumination beams, wherein the two or more illumination beams include at least a first illumination beam having a first wavelength and a second illumination beam having a second wavelength, wherein the first wavelength is different than the second wavelength; and
one or more illumination optics configured to direct the two or more illumination beams to an overlay target on a sample as the sample is scanned relative to the two or more illumination beams along a scan direction when implementing a metrology recipe,
wherein the overlay target in accordance with the metrology recipe includes a grating-over-grating structure in one or more cells, wherein the grating-over-grating structure includes at least a first-layer grating feature on a first layer of the sample and a second-layer grating feature on a second layer of the sample, wherein the first-layer grating feature has a first pitch and the second-layer grating feature has a second pitch different than the first pitch;
a collection sub-system comprising:
two or more photodetectors located in a pupil plane to capture at least one diffraction order of the first illumination beam from the first-layer grating feature and at least one diffraction order of the second illumination beam from the second-layer grating feature of the grating-over-grating structure in the one or more cells when implementing the metrology recipe; and
a controller communicatively coupled to the two or more photodetectors, the controller including one or more processors configured to execute program instructions causing the one or more processors to:
receive time-varying interference signals from the two or more photodetectors associated with the first-layer grating feature and the second-layer grating feature of the grating-over-grating structure in the one or more cells as the overlay target is scanned in accordance with the metrology recipe; and
determine an overlay measurement between one of the first-layer grating feature and the second-layer grating feature of the sample based on the time-varying interference signals.

2. The overlay metrology system of claim 1, wherein the at least one diffraction order of the first illumination beam having the first wavelength from the first-layer grating feature fully overlaps with the at least one diffraction order of the second illumination beam having the second wavelength from the second-layer grating feature.

3. The overlay metrology system of claim 1, wherein a ratio of the first wavelength of the first illumination beam to the first pitch of the first-layer grating feature is equal to the ratio of the second wavelength of the second illumination beam to the second pitch of the second-layer grating feature.

4. The overlay metrology system of claim 1, wherein an illumination intensity of at least one of the first illumination beam or the second illumination beam is adjusted, wherein an intensity of the time-varying interference signals associated with the first-layer grating feature is equal to an intensity of the time-varying interference signals associated with the second illumination beam from the second-layer grating feature.

5. The overlay metrology system of claim 1, wherein the first wavelength of the first illumination beam is selected based on one or more properties of the time-varying interference signals of the first-layer grating feature, wherein the second wavelength of the second illumination beam is selected based on one or more properties of the time-varying interference signals of the second-layer grating feature.

6. The overlay metrology system of claim 5, wherein the one or more properties of the time-varying interference signals of the first-layer grating feature include a contrast above a selected threshold, wherein the one or more properties of the time-varying interference signals of the second-layer grating feature include a contrast above a selected threshold.

7. The overlay metrology system of claim 1, wherein the first-layer grating feature is formed of a first material and at least one of an intermediate-layer grating feature of the second-layer grating feature is formed of a second material, wherein the first material is different than the second material, wherein the first material of the first-layer grating feature absorbs the second wavelength of the second illumination beam, wherein the second material of at least one of the intermediate-layer grating feature of the second-layer grating feature absorbs the first wavelength of the first illumination beam.

8. The overlay metrology system of claim 1, wherein the two or more photodetectors are located in the pupil plane at two or more locations, wherein a first location including a first photodetector includes a location of +1 grating order diffraction associated with grating diffraction from the first-layer grating feature overlapping with 0-order diffraction and grating diffraction from the second-layer grating feature overlapping with the 0-order diffraction, wherein a second location including a second photodetector includes a location of −1 grating order diffraction associated with grating diffraction from the first-layer grating feature overlapping with 0-order diffraction and grating diffraction from the second-layer grating feature overlapping with the 0-order diffraction.

9. The overlay metrology system of claim 1, wherein the one or more processors are configured to execute program instructions causing the one or more processors to:
extract phase information associated with the time-varying interference signals; and
determine the overlay measurement between the first-layer grating feature and the second-layer grating feature of the sample based on the phase information.

10. The overlay metrology system of claim 1, wherein the one or more illumination optics are configured to cause the first illumination beam and the second illumination beam to overlap.

11. The overlay metrology system of claim 1, wherein the one or more illumination optics direct the two or more illumination beams to the overlay target at a normal incidence angle.

12. The overlay metrology system of claim 1, wherein each of the two or more illumination beams comprise a temporally coherent illumination beam.

13. The overlay metrology system of claim 1, further comprising:
a translation stage to translate the sample along the scan direction, wherein the one or more illumination optics direct the two or more illumination beams to the overlay target on the sample as the sample is scanned by the translation stage.

14. The overlay metrology system of claim 1, further comprising:
one or more beam-scanning optics to scan the two or more illumination beams along the scan direction.

15. An overlay metrology system comprising:
a controller communicatively coupled to two or more photodetectors, the controller including one or more processors configured to execute program instructions causing the one or more processors to:
receive time-varying interference signals from the two or more photodetectors associated with a first-layer grating feature and a second-layer grating feature of a grating-over-grating structure in one or more cells as an overlay target on a sample is scanned in accordance with a metrology recipe,
wherein the two or more photodetectors are located in a pupil plane to capture at least one diffraction order of a first illumination beam from the first-layer grating feature and at least one diffraction order of a second illumination beam from the second-layer grating feature of the grating-over-grating structure in the one or more cells when implementing the metrology recipe,
wherein the first illumination beam has a first wavelength and the second illumination beam has a second wavelength, wherein the first wavelength is different than the second wavelength,
wherein the first-layer grating feature has a first pitch and the second-layer grating feature has a second pitch different than the first pitch; and
determine an overlay measurement between one of the first-layer grating feature and the second-layer grating feature of the sample based on the time-varying interference signals.

16. The overlay metrology system of claim 15, wherein the at least one diffraction order of the first illumination beam having the first wavelength from the first-layer grating feature fully overlaps with the at least one diffraction order of the second illumination beam having the second wavelength from the second-layer grating feature.

17. The overlay metrology system of claim 15, wherein a ratio of the first wavelength of the first illumination beam to the first pitch of the first-layer grating feature is equal to the ratio of the second wavelength of the second illumination beam to the second pitch of the second-layer grating feature.

18. The overlay metrology system of claim 15, wherein an illumination intensity of at least one of the first illumination beam or the second illumination beam is adjusted, wherein an intensity of the time-varying interference signals associated with the first-layer grating feature is equal to an intensity of the time-varying interference signals associated with the second illumination beam from the second-layer grating feature.

19. The overlay metrology system of claim 15, wherein the first wavelength of the first illumination beam is selected based on one or more properties of the time-varying interference signals of the first-layer grating feature, wherein the second wavelength of the second illumination beam is selected based on one or more properties of the time-varying interference signals of the second-layer grating feature.

20. The overlay metrology system of claim 19, wherein the one or more properties of the time-varying interference signals of the first-layer grating feature include a contrast above a selected threshold, wherein the one or more properties of the time-varying interference signals of the second-layer grating feature include a contrast above a selected threshold.

21. The overlay metrology system of claim 15, wherein the first-layer grating feature is formed of a first material and at least one of an intermediate-layer grating feature of the second-layer grating feature is formed of a second material, wherein the first material is different than the second material, wherein the first material of the first-layer grating feature absorbs the second wavelength of the second illumination beam, wherein the second material of at least one of the intermediate-layer grating feature of the second-layer grating feature absorbs the first wavelength of the first illumination beam.

22. A method comprising:
illuminating an overlay target on a sample as the sample is translated along a scan direction with two or more illumination beams, wherein the two or more illumination beams include at least a first illumination beam having a first wavelength and a second illumination beam having a second wavelength, wherein the first wavelength is different than the second wavelength;
receiving time-varying interference signals from two or more photodetectors associated with a first-layer grating feature and a second-layer grating feature of a grating-over-grating structure in one or more cells as the overlay target is scanned in accordance with a metrology recipe, wherein the two or more photodetectors are located in a pupil plane to capture at least one diffraction order of the first illumination beam from the first-layer grating feature and at least one diffraction order of the second illumination beam from the second-layer grating feature of the grating-over-grating structure in the one or more cells when implementing the metrology recipe, wherein the first-layer grating feature has a first pitch and the second-layer grating feature has a second pitch different than the first pitch; and
determining an overlay measurement between one of the first-layer grating feature and the second-layer grating feature of the sample based on the time-varying interference signals.

23. The method of claim 22, wherein the at least one diffraction order of the first illumination beam having the first wavelength from the first-layer grating feature fully overlaps with the at least one diffraction order of the second illumination beam having the second wavelength from the second-layer grating feature.

24. The method of claim 22, wherein a ratio of the first wavelength of the first illumination beam to the first pitch of the first-layer grating feature is equal to the ratio of the second wavelength of the second illumination beam to the second pitch of the second-layer grating feature.

25. The method of claim 22, wherein an illumination intensity of at least one of the first illumination beam or the second illumination beam is adjusted, wherein an intensity of the time-varying interference signals associated with the first-layer grating feature is equal to an intensity of the time-varying interference signals associated with the second illumination beam from the second-layer grating feature.

26. The method of claim 22, wherein the first wavelength of the first illumination beam is selected based on one or more properties of the time-varying interference signals of the first-layer grating feature, wherein the second wavelength of the second illumination beam is selected based on one or more properties of the time-varying interference signals of the second-layer grating feature.

27. The method of claim 26, wherein the one or more properties of the time-varying interference signals of the first-layer grating feature include a contrast above a selected threshold, wherein the one or more properties of the time-varying interference signals of the second-layer grating feature include a contrast above a selected threshold.

28. The method of claim 22, wherein the first-layer grating feature is formed of a first material and at least one of an intermediate-layer grating feature of the second-layer grating feature is formed of a second material, wherein the first material is different than the second material, wherein the first material of the first-layer grating feature absorbs the second wavelength of the second illumination beam, wherein the second material of at least one of the intermediate-layer grating feature of the second-layer grating feature absorbs the first wavelength of the first illumination beam.
